(19) United States
(12) Patent Application Publication
(10) Pub. No.: US 2011/0176282 A1
(43) Pub. Date: Jul. 21, 2011

(54) FLAT PANEL DISPLAY DEVICE AND COMMON MODE FILTER USED THEREFOR

(75) Inventors: Deuk Hoon KIM, Incheon (KR); Jong Hae KIM, Suwon (KR); Young Se KIM, Suwon (KR); Sang Joon SEO, Suwon (KR); Heung Gyoon CHOI, Suwon (KR); Young Min LEE, Suwon (KR); Myeong Sik CHEON, Suwon (KR)

(73) Assignee: SAMSUNG ELECTRO-MECHANICS CO., LTD., Gyunggi-do (KR)

(21) Appl. No.: 13/009,555

(22) Filed: Jan. 19, 2011

(30) Foreign Application Priority Data
Jan. 20, 2010 (KR) 1020100005325
Oct. 20, 2010 (KR) 1020100102567

(51) Int. Cl. H05K 5/00; H05K 7/00

(52) U.S. Cl. 361/752; 361/748

(57) ABSTRACT

There is provided a flat panel display device, including: a display panel; a printed circuit board on which a circuit component driving the display panel is mounted; a common mode filter mounted on the printed circuit board and including coils wound in parallel with the printed circuit board; and a cover protecting the display panel and the printed circuit board.

### CROSS-REFERENCE TO RELATED APPLICATIONS

This application claims the priority of Korean Patent Application Nos. 10-2010-0005325 filed on Jan. 20, 2010 and 10-2010-0102567 filed on Oct. 20, 2010, in the Korean Intellectual Property Office, the disclosures of which are incorporated herein by reference.

### BACKGROUND OF THE INVENTION

1. Field of the Invention

The present invention relates to a flat panel display device and a common mode filter used therefor.

2. Description of the Related Art

Recently, research into a technology for reducing the overall size of a product and allowing it to have a slim appearance in the market the flat panel display (FPD) such as a liquid crystal display (LCD), a plasma display panel (PDP), organic light emitting diode (OLED), or the like has been actively conducted.

In particular, in order to raise the emotional response quality of a display device, the need to reduce the thickness of a product is an ongoing requirement.

A common mode filter applied to the product of the flat panel display device includes a coil component wound around a core. As the coil component, a toroidal type coil component is generally used.

Since the toroidal type coil component assembles an insulating bobbin with a toroidal shaped core and winds a neutral line and a live line of the coil on the assembled core in opposite directions, it may not be automatically produced, such that production speed thereof is slow and component cost thereof is raised.

Meanwhile, when a coil component of the general common mode filter including the toroidal type coil component is mounted on a printed circuit board, a coil is wound in a direction perpendicular to the printed circuit board, that is, in a clockwise direction or a counterclockwise direction when viewing the printed circuit board from the side.

If the coil component of the common mode filter is applied to a slim flat panel display, a distance between the coil component mounted on the printed circuit board and a back cover of the flat panel display is reduced.

If the distance between the coil component and the back cover is reduced, a magnetic flux generated outside the coil of the coil component interferes in the back cover, thereby causing noise.

### SUMMARY OF THE INVENTION

An aspect of the present invention provides a common mode filter having a structure in which a coil is wound in a direction in parallel with a printed circuit board.

Another aspect of the present invention provides a flat panel display device capable of making a winding direction of a coil of a common mode filter mounted on a printed circuit board parallel with the printed circuit board to reduce an effect of a magnetic flux of the common mode filter.

According to an aspect of the present invention, there is provided a flat panel display device, including: a display panel; a printed circuit board on which a circuit component driving the display panel is mounted; a common mode filter mounted on the printed circuit board and including coils wound in parallel with the printed circuit board; and a cover protecting the display panel and the printed circuit board

The coils may be wound in a clockwise direction or in a counterclockwise direction when viewing the printed circuit board from the above.

The common mode filter may include a bobbin having the coils wound thereon; and a core coupled with the bobbin to provide a magnetic flux.

The coils may include a neutral coil and a live coil, the neutral coil and the live coil being wound, while being partitioned by a partition wall formed in the bobbin.

The bobbin may include a base plate having a lead frame, the lead frame being electrically connected to the coils to be connected to the printed circuit board.

The base plate may be in parallel with the partition wall, and may be in parallel with the printed circuit board when viewing of the printed circuit board from the side.

The base plate may be disposed at a location higher than that of the partition wall from the printed circuit board.

The lead frame may be reversely disposed on the printed circuit board so that the partition wall is positioned over the printed circuit board.

A portion of the partition wall may be received in an opening of the printed circuit board.

The base plate may be seated in an opening of the printed circuit board.

The coils may include a neutral coil and a live coil, the neutral coil and the live coil being wound, while being partitioned by a base plate formed on the bobbin and including the lead frame electrically connected to the neutral coil and the live coil to be connected to the printed circuit board.

The base plate may be in parallel with the partition wall, and may be in parallel with the printed circuit board when viewing the printed circuit board from the side.

The base plate may be seated in an opening of the printed circuit board.

One of the neutral coil and the live coil may be wound on the bobbin in a direction from the printed circuit board to the display panel and another coil may be wound on the bobbin in a direction from the printed circuit board to a back cover.

According to another aspect of the present invention, there is provided a common mode filter, including: a lead frame electrically connected to coils and coupled with a printed circuit board of a flat panel display device; a bobbin including a base plate having the lead frame; and a core coupled with the bobbin to provide a magnetic flux, wherein the coils are wound in parallel with the printed circuit board when viewing the printed circuit board from the side.

The coils may be wound in a clockwise direction or in a counterclockwise direction when viewing the printed circuit board from the above.

The coils may include a neutral coil and a live coil, the neutral coil and the live coil being wound, while being partitioned by a partition wall formed in the bobbin.

The base plate may be in parallel with the partition wall, and may be in parallel with the printed circuit board when viewing the printed circuit board from the side.

The base plate may be disposed at a location higher than that of the partition wall from the printed circuit board.

The lead frame may be reversely disposed on the printed circuit board so that the partition wall is positioned over the printed circuit board.

The partition wall may include a cutting groove in order to facilitate introduction of impregnation liquid.

The coils may include a neutral coil and a live coil, the neutral coil and the live coil being wound, while being partitioned by a base plate.

The core may be an E type core having outer leg portions and a central leg portion formed on a core body.

The core may be a U type core having leg portions formed on both ends of a core body.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic exploded perspective view of a flat panel display device according to an exemplary embodiment of the present invention;

FIG. 2 is a schematic perspective view of a shape in which a common mode filter is mounted on a printed circuit board according to an exemplary embodiment of the present invention;

FIG. 3 a schematic exploded perspective view of a common mode filter according to an exemplary embodiment of the present invention;

FIG. 4 is a cross-sectional view of a common mode filter to which a core according to a first exemplary embodiment of the present invention is applied;

FIG. 5 is a cross-sectional view of a common mode filter to which a core according to a second exemplary embodiment of the present invention is applied;

FIG. 6 is a schematic perspective view of a shape in which a common mode filter is mounted on a printed circuit board having an opening formed therein according to an exemplary embodiment of the present invention;

FIG. 7 is a schematic perspective view of a shape in which a common mode filter is reversely mounted on a printed circuit board having an opening formed therein according to another exemplary embodiment of the present invention;

FIG. 8 is a schematic perspective view of a shape in which a common mode filter is mounted on a printed circuit board having an opening formed therein according to another exemplary embodiment of the present invention; and

FIG. 9 is a schematic view showing a flow of a magnetic flux generated in a coil of a common mode filter within a flat panel display device according to an exemplary embodiment of the present invention.

### DETAILED DESCRIPTION OF THE PREFERRED EMBODIMENT

Hereinafter, exemplary embodiments of the present invention will be described in detail with reference to the accompanying drawings. However, it should be noted that the spirit of the present invention is not limited to the embodiments set forth herein and those skilled in the art and understanding the present invention could easily accomplish retrogressive inventions or other embodiments included in the spirit of the present invention by the addition, modification, and removal of components within the same spirit, but those are construed as being included in the spirit of the present invention.

Further, like reference numerals will be used to designate like components having similar functions throughout the drawings within the scope of the present invention.

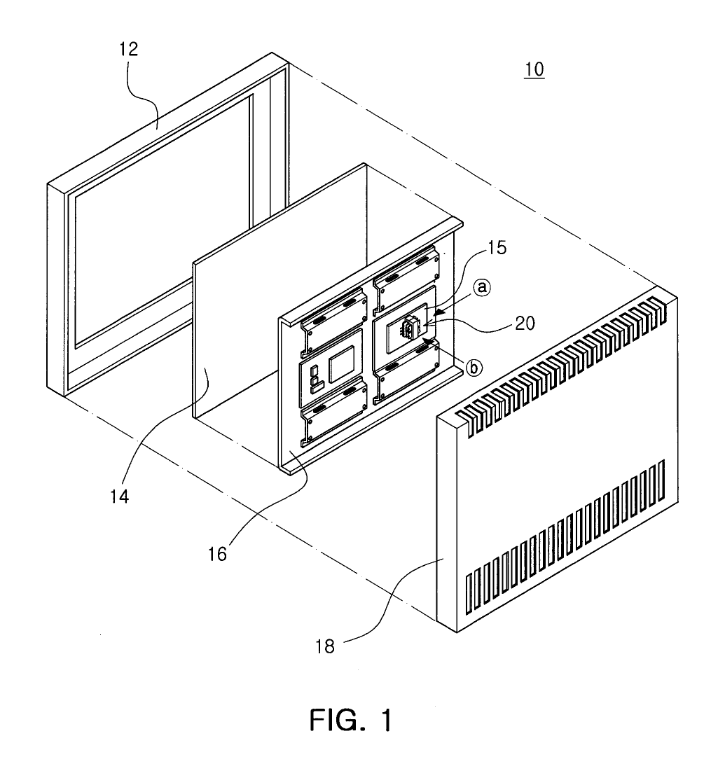

FIG. 1 is a schematic exploded perspective view of a flat panel display device according to an exemplary embodiment of the present invention.

Referring to FIG. 1, a flat panel display device 10 according to an exemplary embodiment of the present invention may include a display panel 14, a printed circuit board 15, a common mode filter 20, and a cover 18.

The cover 18 may be a back cover distinguished from a front case 12 and form an inner space together with the front case 12, as shown in FIG. 1.

The display panel 14 is disposed in the inner space. As the display panel, a liquid crystal display (LCD), a plasma display panel (PDP), an organic light emitting diode (OLED), and the like, may be used.

The display panel 14 is electrically connected to the printed circuit board 15 on which a circuit component driving the display panel 14 is mounted.

The printed circuit board 15 and the display panel 14 may be fixed to the front case 12 and the back cover 18 by a chassis 16.

The common mode filter 20 has a coil wound in parallel with the printed circuit board 15 when viewing the printed circuit board 15 from the side (an arrow □ direction). That is, the coil may be wound in a clockwise direction or in a counterclockwise direction when viewing the printed circuit board 15 from the above (an arrow □ direction).

Hereinafter, technical features of a common mode filter 20 according to an exemplary embodiment of the present invention will be described in detail. The flat panel display device 10 may have all of the technical features of the common mode filter 20 described below.

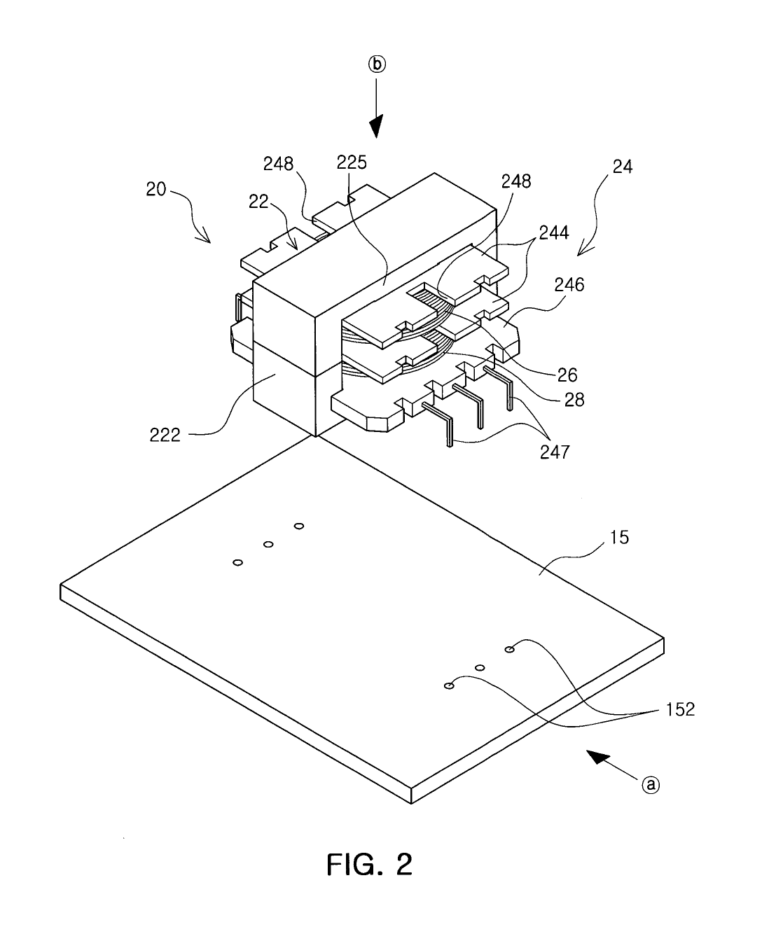

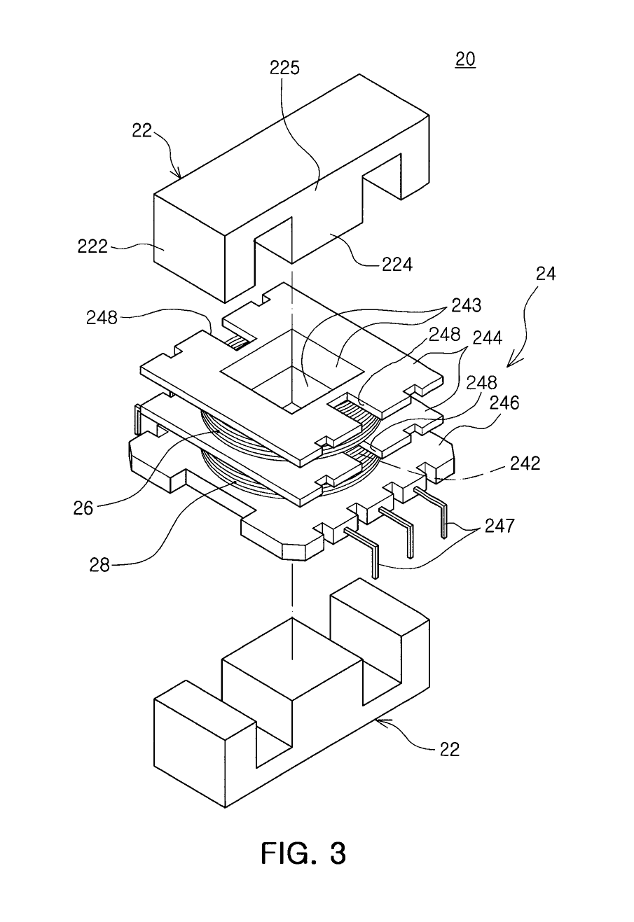

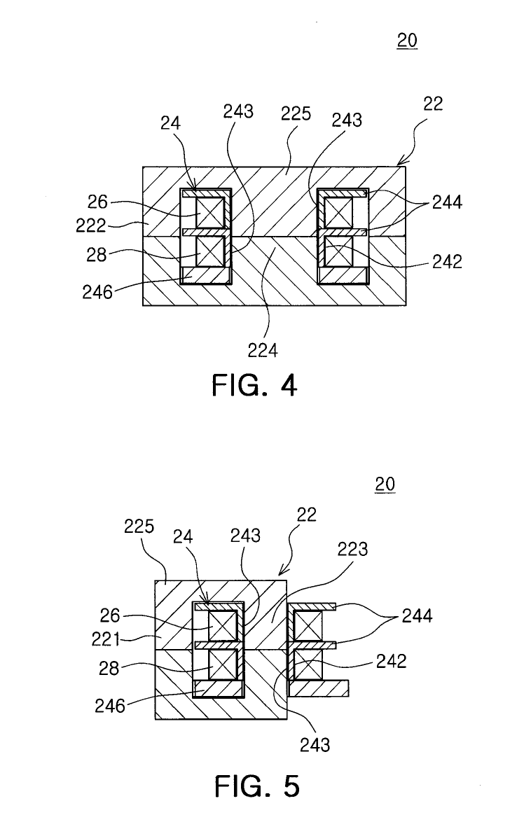

FIG. 2 is a schematic perspective view of a shape in which a common mode filter is mounted on a printed circuit board according to an exemplary embodiment of the present invention, FIG. 3 a schematic exploded perspective view of a common mode filter according to an exemplary embodiment of the present invention, and FIG. 4 is a cross-sectional view of a common mode filter to which a core according to a first exemplary embodiment of the present invention is applied.

Referring to FIGS. 2 to 4, the common mode filter 20 according to the exemplary embodiment of the present invention may include a bobbin 24 on which coils 26 and 28 are wound and a core 22 coupled with the bobbin 24 to provide a magnetic flux.

The bobbin 24 is electrically connected to the coils 26 and 28, and may include a base plate 246 having a lead frame 247 coupled with the printed circuit board 15 of the flat panel display device 10. Herein, since the base plate 246 includes the lead frame 247, a plate coupled with the printed circuit board 15 is defined as a base plate.

The bobbin 24 includes a bobbin body having a rectangular cross section. The bobbin body 242 is formed with a core insertion hole 243 into which a central leg portion 224 of the core 22 is inserted, and the coils 26 and 28 are wound on an outer peripheral surface of the bobbin body 242. A cross-sectional shape of the bobbin 24 may not be specially limited if it has a structure for automatic winding.

The core 22 according to the first exemplary embodiment is an E type core having outer leg portions 222 and the central leg portion 224 formed on a core body 225. The central leg portions 224 of two E type cores may be inserted into the core insertion hole 243 and be fixedly bonded to each other.

Herein, the coil includes a neutral coil 26 and a live coil 28, wherein the neutral coil 26 and the live coil 28 may be wound, while being partitioned by a partition wall 244 formed in the bobbin 24. The neutral coil 26 and the live coil 28 are wound in the same direction, thereby performing a noise filtering function.

During the process of winding the neutral coil 26 and the live coil 28 on the bobbin 24 and then impregnating the wound coils with varnish, the partition wall 244 may be provided with a cutting part 248 in order to facilitate the introduction of impregnation liquid into the wound coils 26 and 28.

The neutral coil 26 and the live coil 28 may be wound in parallel with the printed circuit board 15 when viewing the printed circuit board 15 from the side (an arrow D direction).

Herein, the base plate 246 is in parallel with the partition wall 244, and is in parallel with the printed circuit board 15 when viewing the printed circuit board 15 from the side (an arrow □ direction).

It is possible to accomplish the automation of coil winding by the bobbin 24 including the partition wall 244 and the base plate 246 formed in parallel with each other.

The neutral coil 26 and the live coil 26 may be wound in a clockwise direction or in a counterclockwise direction when viewing the printed circuit board 15 and the base plate 246 from the above (an arrow □ direction).

FIG. 5 is a cross-sectional view of a common mode filter to which a core according to a second exemplary embodiment of the present invention is applied.

Referring to FIG. 5, a core 22 according to the second exemplary embodiment may be a U-shaped core having two leg portions formed on both ends of the core body 225. At least one of the leg portions 221 and 223 is inserted into the core insertion hole 243 formed in the bobbin 24, and the core 22 may be coupled with the bobbin 24.

The common mode filter 20 to which the core 22 according to the second exemplary embodiment is applied may also have all of technical features of the common mode filter 20 according to the first exemplary embodiment described with reference to FIGS. 2 to 4.

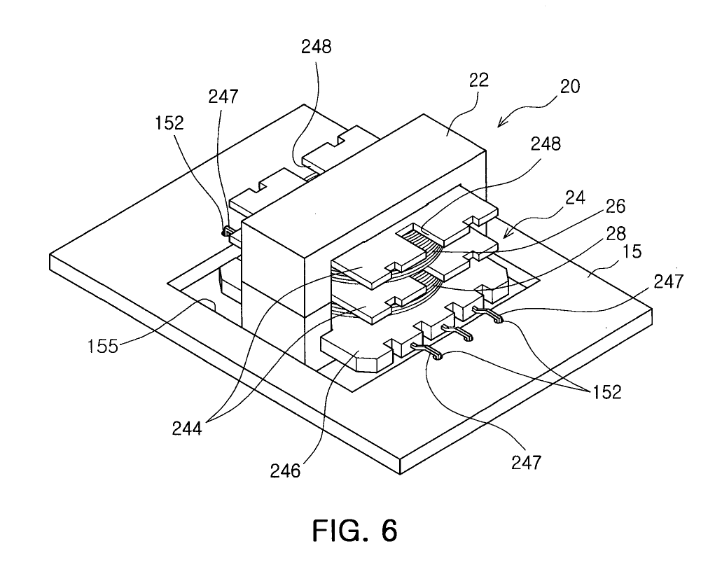

FIG. 6 is a schematic perspective view of a shape in which a common mode filter is mounted on a printed circuit board having an opening formed therein according to an exemplary embodiment of the present invention.

Referring to FIG. 6, it may be appreciated that the common mode filter 20 according to the embodiment described with reference to FIGS. 3 and 4 is mounted on the printed circuit board 15.

In the common mode filter 20 according to the embodiment described with reference to FIGS. 3 and 4, the base plate 246 constituting the bobbin 24 is formed on a bottom layer from the printed circuit board 15, and the bobbin body 242 is formed on an upper portion of the base plate 246.

The base plate 246 according to the second exemplary embodiment may be seated in an opening 155 of the printed circuit board 15. As such, the opening 155 is formed in the printed circuit board 15 to mount the common mode filter 20 therein, thereby making it possible to make the whole flat panel display device 10 slim.

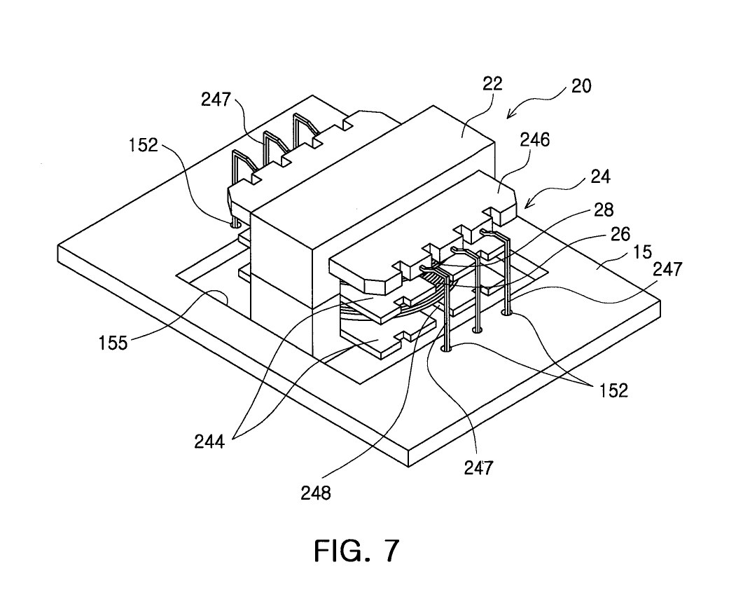

FIG. 7 is a schematic perspective view of a shape in which a common mode filter is reversely mounted on a printed circuit board having an opening formed therein according to another exemplary embodiment of the present invention.

Referring to FIG. 7, it may be appreciated that the common mode filter 20 is reversely mounted on the printed circuit board 15.

In the common mode filter 20 according to the present embodiment, the base plate 246 constituting the bobbin 24 is formed on a top layer from the printed circuit board 15, and the bobbin body 242 is formed on an lower portion of the base plate 246.

That is, the base plate 246 may be disposed at a location higher than that of the partition wall 244 from the printed circuit board 15.

Herein, the lead frame 247 extended from the base plate 246 may be reversely disposed on the printed circuit board 15 so that the partition wall 244 is positioned over the printed circuit board 15.

In addition, a portion of the partition wall 244 may be received in an opening 155 of the printed circuit board 15. As such, a portion of the partition wall 244 of the common mode filter 20 is received in the opening 155 of the printed circuit board 15, thereby making it possible to make the whole flat panel display device 10 slim.

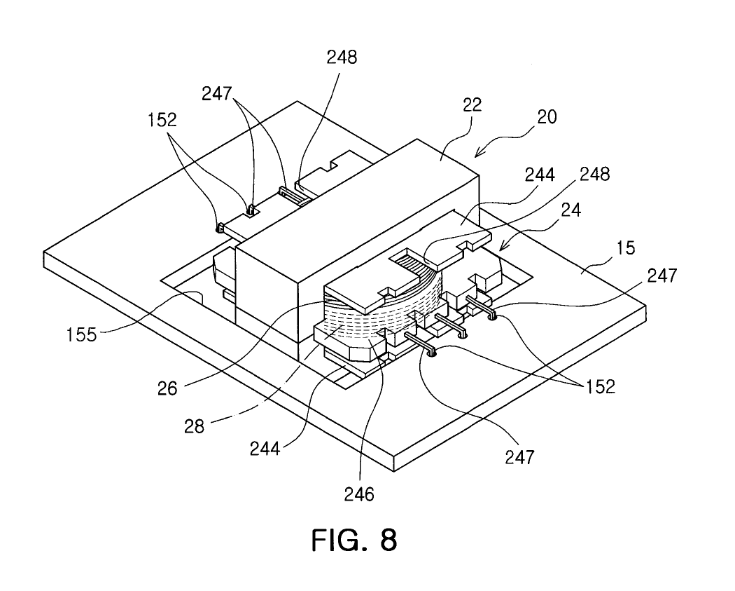

FIG. 8 is a schematic perspective view of a shape in which a common mode filter is mounted on a printed circuit board having an opening formed therein according to another exemplary embodiment of the present invention.

Referring to FIG. 8, it may be appreciated that the common mode filter 20 according to another exemplary embodiment of the present invention is mounted on the printed circuit board 15.

In the common mode filter 20 according to the present embodiment, the neutral coil 26 and the live coil 28 may be wound, while being partitioned by the base plate 246 formed on the bobbin 24 and including the lead frame 247 electrically connected to the neutral coil 26 and the live coil 28 to be connected to the printed circuit board 15.

The bobbin 24 according to the present embodiment may include the partition walls 244 disposed in parallel with each other up and down based on the base plate 246.

The base plate 246 according to the present embodiment may be seated in the opening 155 of the printed circuit boar 15. As the base plate 246 is seated in the opening 155 of the printed circuit board 15, one of the neutral coil 26 and the live coil may be wound on the bobbin 24 in a direction from the printed circuit board 15 to the display panel 14 and another coil may be wound on the bobbin 24 in a direction from the printed circuit board 15 to the back cover 18.

In the case of using the printed circuit board 15 to which the common mode filter 20 according to the present embodiment is applied, an overall thickness of the flat panel display 10 may become slimmer as compared to the embodiment described with reference to FIG. 6.

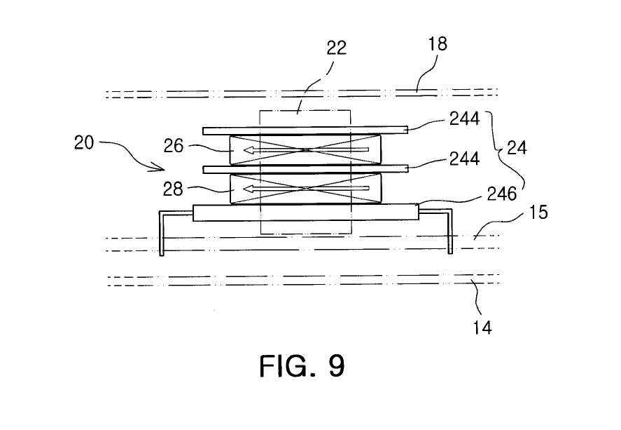

FIG. 9 is a schematic view showing flow of a magnetic flux generated in a coil of a common mode filter within a flat panel display device according to an exemplary embodiment of the present invention.

Referring to FIG. 9, the neutral coil 26 and the live coil 28 are wound in parallel with the printed circuit board 15, such that a magnetic flux of the coils is formed in an arrow direction unlike an existing case in which the coils are wound in a direction perpendicular to the printed circuit board 15.

That is, the direction of the magnetic flux is in parallel with the back cover 18, such that interference does not occur between the magnetic flux and the back cover 18 of the flat display device 10.

According to the flat display panel device and the common mode filter used therefor of the exemplary embodiments of the present invention, the coils are horizontally wound on the bobbin having the partition wall and the lead frame in parallel with the printed circuit board, when viewing the printed circuit board from the side, thereby making it possible to accomplish automation in producing the coil component and reduce processing cost of the coil component.

Meanwhile, according to the flat display panel device and the common mode filter used therefor of the exemplary embodiments of the present invention, although the thickness of the flat panel display device becomes slim to shorten a distance between the printed circuit board and the back cover, the coils of the common mode filter are wound horizontally to the printed circuit board, thereby allowing the magnetic flux generated from the coil not to have a direct effect on the back cover.

It is possible to remarkably reduce noise due to the effect of the back cover on the magnetic flux.

While the present invention has been shown and described in connection with the exemplary embodiments, it will be apparent to those skilled in the art that modifications and variations can be made without departing from the spirit and scope of the invention as defined by the appended claims.

What is claimed is:

1. A flat panel display device, comprising:
a display panel;
a printed circuit board on which a circuit component driving the display panel is mounted;
a common mode filter mounted on the printed circuit board and including coils wound in parallel with the printed circuit board; and
a cover protecting the display panel and the printed circuit board.

2. The flat panel display device of claim 1, wherein the coils are wound in a clockwise direction or in a counterclockwise direction when viewing the printed circuit board from the above.

3. The flat panel display device of claim 1, wherein the common mode filter includes:
a bobbin having the coils wound thereon; and
a core coupled with the bobbin to provide a magnetic flux.

4. The flat panel display device of claim 3, wherein the coils include a neutral coil and a live coil, the neutral coil and the live coil being wound, while being partitioned by a partition wall formed in the bobbin.

5. The flat panel display device of claim 4, wherein the bobbin includes a base plate having a lead frame, the lead frame being electrically connected to the coils to be connected to the printed circuit board.

6. The flat panel display device of claim 5, wherein the base plate is in parallel with the partition wall, and is in parallel with the printed circuit board when viewing the printed circuit board from the side.

7. The flat panel display device of claim 5, wherein the base plate is disposed at a location higher than that of the partition wall from the printed circuit board.

8. The flat panel display device of claim 7, wherein the lead frame is reversely disposed on the printed circuit board so that the partition wall is positioned over the printed circuit board.

9. The flat panel display device of claim 8, wherein a portion of the partition wall is received in an opening of the printed circuit board.

10. The flat panel display device of claim 5, wherein the base plate is seated in an opening of the printed circuit board.

11. The flat panel display device of claim 3, wherein the coils include a neutral coil and a live coil, the neutral coil and the live coil being wound, while being partitioned by a base plate formed on the bobbin and including the lead frame electrically connected to the neutral coil and the live coil to be connected to the printed circuit board.

12. The flat panel display device of claim 11, wherein the base plate is in parallel with the partition wall, and is in parallel with the printed circuit board when viewing the printed circuit board from the side.

13. The flat panel display device of claim 11, wherein the base plate is seated in an opening of the printed circuit board.

14. The flat panel display device of claim 13, wherein one coil of the neutral coil and the live coil are wound on the bobbin in a direction from the printed circuit board to the display panel and another coil is wound on the bobbin in a direction from the printed circuit board to a back cover.

15. A common mode filter, comprising:
a lead frame electrically connected to coils and coupled with a printed circuit board of a flat panel display device;
a bobbin including a base plate having the lead frame; and
a core coupled with the bobbin to provide a magnetic flux,
wherein the coils are wound in parallel with the printed circuit board when viewing the printed circuit board from the side.

16. The common mode filter of claim 15, wherein the coils are wound in a clockwise direction or in a counterclockwise direction when viewing the printed circuit board from the above.

17. The common mode filter of claim 15, wherein the coils include a neutral coil and a live coil, the neutral coil and the live coil being wound, while being partitioned by a partition wall formed in the bobbin.

18. The common mode filter of claim 17, wherein the base plate is in parallel with the partition wall, and is in parallel with the printed circuit board when viewing the printed circuit board from the side.

19. The common mode filter of claim 17, wherein the base plate is disposed at a location higher than that of the partition wall from the printed circuit board.

20. The common mode filter of claim 19, wherein the lead frame is reversely disposed on the printed circuit board so that the partition wall is positioned over the printed circuit board.

21. The common mode filter of claim 17, wherein the partition wall includes a cutting groove in order to facilitate introduction of impregnation liquid.

22. The common mode filter of claim 15, wherein the coils include a neutral coil and a live coil, the neutral coil and the live coil being wound, while being partitioned by a base plate.

23. The common mode filter of claim 15, wherein the core is an E type core having outer leg portions and a central leg portion formed on a core body.

24. The common mode filter of claim 15, wherein the core is a U type core having leg portions formed on both ends of a core body.
